(19) United States
(12) Patent Application Publication
(10) Pub. No.: US 2005/0263342 A1
(43) Pub. Date: Dec. 1, 2005

(54) Speaker fixture assembly

(75) Inventor: Jack Peng, Taipei (TW)

Correspondence Address: TROXELL LAW OFFICE PLLC, SUITE 1404, 5205 LEESBURG PIKE, FALLS CHURCH, VA, 22041, US

(73) Assignee: Meiloon Industrial Co., Ltd.

(21) Appl. No.: 10/853,258

(22) Filed: May 26, 2004

(51) Int. Cl. H05K 5/00

(52) U.S. Cl. 181/153; 181/150

(57) ABSTRACT

The present invention discloses an improved speaker fixture assembly, comprising a speaker and a speaker fixing board disposed on the loudspeaker box; wherein the main body of the speaker has a frame at its exterior and a locking hole on the frame, and the speaker fixing board has an accommodating hole disposed in the middle for mounting the main body of the speaker and at least one locking hole disposed at the outer side of the corresponding fixing board and frame; and a clamping section being a “h”-shaped protruded member disposed at the edge of the main body of the speaker and the frame and having a clamping opening and a groove for accommodating the board for clamping the fixing board onto the accommodating hole, such that the speaker can be installed or disassembled easily by a screw and a clamping section.

### BACKGROUND OF THE INVENTION

1. Field of the Invention

The present invention relates to an improved speaker fixture, more particularly to an improved simple-structured and easy-to-manufacture speaker fixture which uses a clamping bracket and a screw to fix the speaker, and makes the installation and disassembly of the speaker simpler and easier.

2. Description of the Related Art

As our living standard is improved, the stereo equipment has become an indispensable electric appliance for families and individuals. Therefore, the way of simplifying the application and assembling the equipment is the current pursuing topics, and there are many different designs for various speaker structures such as the typical example of the R.O.C. utility patent as described below.

The R.O.C. Publication No. 570467 disclosed an improved car loudspeaker assembly, which comprises a main loudspeaker box, a top panel, a speaker decorative panel and a screw set, wherein the main loudspeaker box has an accommodating space in the middle and the top panel is coupled to the top of the main loudspeaker box, characterized in that a stairway-like square groove is disposed at the center of the top panel; the outer frame of the speaker decorative panel is designed according to the size of the square groove; a plurality of screw holes is disposed at the periphery; a disposing hole is disposed at the center of the decorative speaker panel in correspondence with the quantity and size of the speaker sets. The screw set further comprises a decorative lid, a screw and a bottom lock bracket, such that the decorative speaker panel is installed onto the top panel by the screw set to maintain the artistic look after the installation. Users just need to change the decorative speaker panel when the quantity or size of the speaker sets is changed.

However, various traditional speaker assembly designs come with several screws, and it will increase the number of assembling components, the manufacturing cost and the time.

### SUMMARY OF THE INVENTION

In view of the foregoing shortcomings of the prior art, the inventor of the present invention conducted extensive researches and experiments, and finally invented the improved speaker fixture assembly in accordance with the present invention.

The primary objective of the present invention is to provide a novel improved simple-structure and easy-to-manufacture speaker fixture assembly that uses a clamping bracket and a screw to fix the speaker and makes the installation and disassembly of the speaker simple and easy.

### BRIEF DESCRIPTION OF THE DRAWINGS

FIG. 1 is a perspective view of most of the disassembled parts of the loudspeaker box of the present invention.

FIG. 2 is a perspective view of the assembled speaker of the present invention.

FIG. 3 is a perspective view of the disassembled speaker of the present invention.

FIG. 4 is a cross-sectional view of the disassembled speaker of the present invention.

FIG. 5 is a perspective view of the fixture board being directly designed as the loudspeaker panel according to the present invention.

### DETAILED DESCRIPTION OF THE PREFERRED EMBODIMENTS

To achieve the foregoing objective, the improved speaker fixture assembly according to the present invention comprises a speaker and a speaker fixing board disposed on the loudspeaker box; wherein the main body of the speaker has a frame at its exterior and a locking hole on the frame, and the speaker fixing board has an accommodating hole disposed in the middle for mounting the main body of the speaker and at least one locking hole disposed at the outer side of the corresponding fixing board and frame; and a clamping section being a “h”-shaped protruded member disposed at the edge of the main body of the speaker and the frame and having a clamping opening and a groove for accommodating the board for clamping the fixing board onto the accommodating hole, such that the speaker can be installed or disassembled easily by a screw and a clamping section.

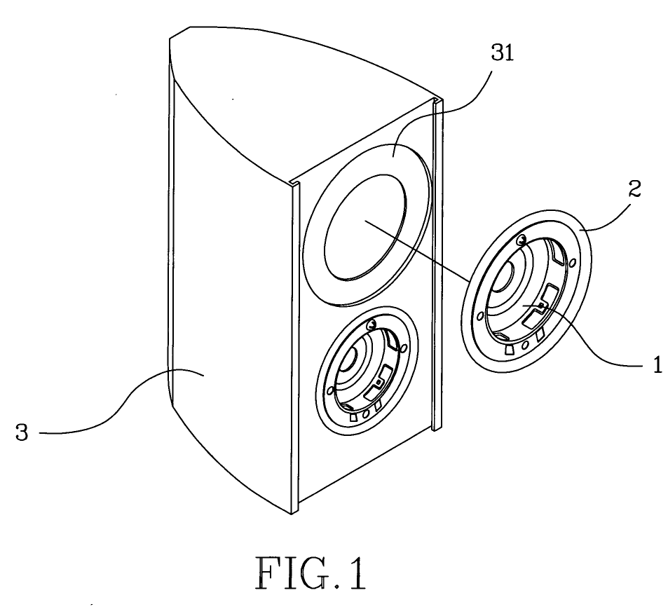

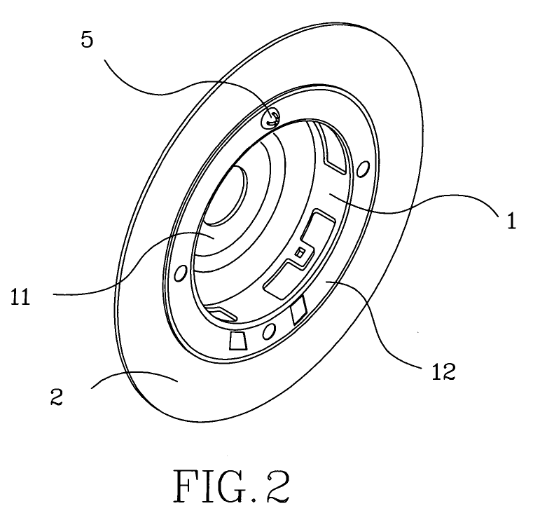

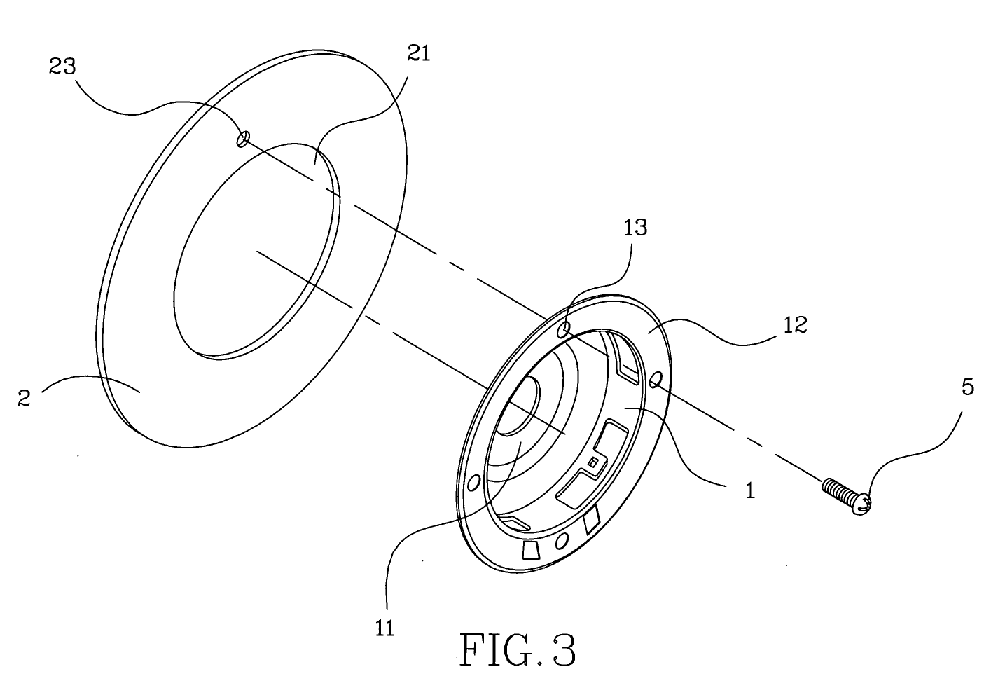

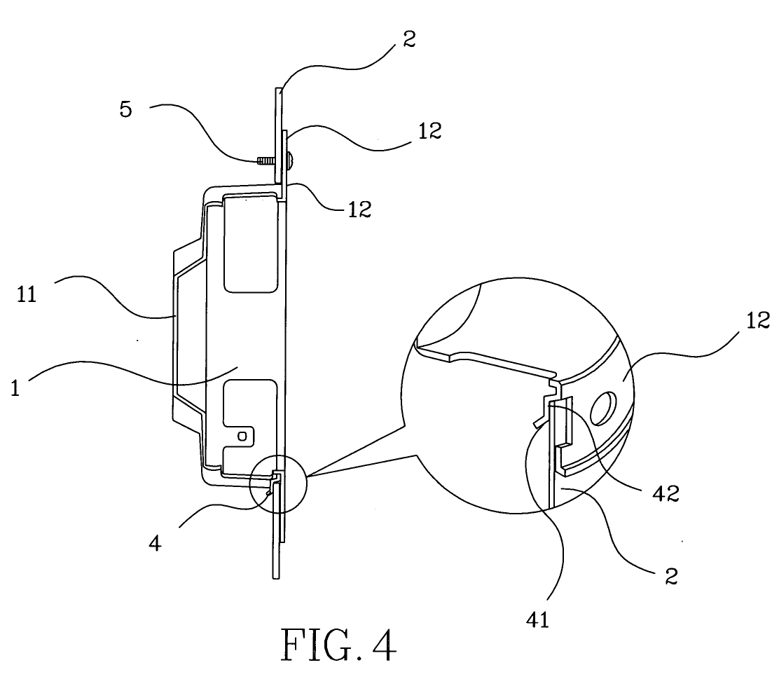

Please refer to FIGS. 1 to 5 for an improved speaker fixture assembly of the present invention, which comprises a speaker 1 and a speaker fixing board 2 disposed on a loudspeaker box 3; wherein a main body 11 has a frame 12 at its exterior and the frame 12 has a locking hole 13; the speaker fixing board 2 has an accommodating hole 21 in the middle for accommodating the main body 11 of the speaker 1, and a locking hole 23 disposed at the corresponding outer edge of the fixing board 2 and the frame 12; and a clamping section 4, being a h-shaped protrusion disposed on the edge of the main body 11 of the speaker 1 and the frame 12 and having a clamping opening 41 and a groove 42 for accommodating the fixing board 2 to clamp the speaker 1 onto the accommodating hole 21 of the fixing board 2; so that when the speaker 1 is mounted, the clamping opening 41 is used to align one side of the speaker 1 at the accommodating hole 21 of the fixing board 2, and the groove 42 for accommodating the fixing board 2 is used to clamp the speaker 1 onto the accommodating hole 21 of the fixing board 2, and a screw 5 passes through the locking hole 13, 23 on the other side to mount the speaker in a simple manner and makes the installation and disassembly of the speaker simpler and easier.

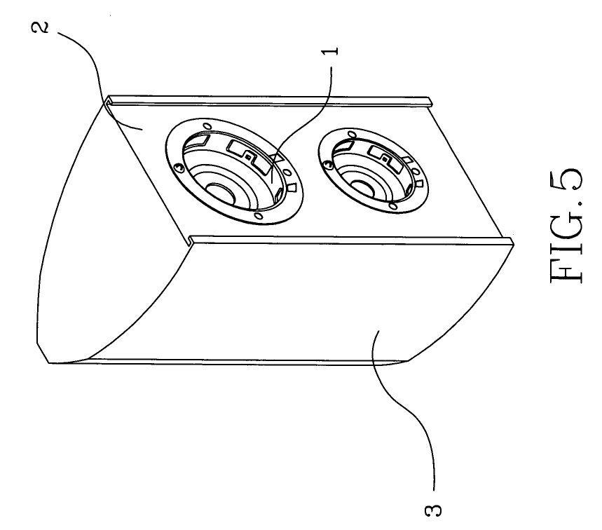

The fixing board 2 as shown in FIG. 1 is a circular board, which can be inserted into a stairway-like groove hole 31 disposed on the panel of the loudspeaker box 3 as shown in FIG. 5. The fixing board 2 can be designed as the panel of the loudspeaker box 3, so that the structure can fit various kinds of loudspeaker boxes 3. Further, the clamping opening 41 of the clamping section 4 could be aslant to facilitate the insertion with the accommodating hole 21 and makes the installation much easier.

In summation of the description above, the assembly of the invention is simple structured and easy-to-manufacture, and the design utilizes a clamping section and a screw to achieve the simple mounting of the speaker and makes the installation and disassembly of the speaker simpler and easier. The present invention overcomes the shortcomings of the prior-art assemblies and applications, and enhances the performance than the conventional structure and further complies with the patent application requirements and is submitted to the Patent and Trademark Office for review and granting of the commensurate patent rights.

While the invention has been described by way of example and in terms of a preferred embodiment, it is to be understood that the invention is not limited thereto. To the contrary, it is intended to cover various modifications and similar arrangements and procedures, and the scope of the appended claims therefore should be accorded the broadest interpretation so as to encompass all such modifications and similar arrangements.

1. An improved speaker fixture assembly comprising a speaker and a speaker fixing board disposed on a loudspeaker box; characterized in that:
said speaker, comprising a frame disposed on the exterior of a main body;
said speaker fixing board, comprising an accommodating hole in the middle for accommodating said main body of said speaker and at least one locking hole disposed at the corresponding outer edge of said fixing board and said frame; and
a clamping section, being a h-shaped protrusion disposed at the edge of said main body of said speaker and said frame and having a clamping opening and accommodating groove for accommodating said fixing board for clamping said speaker onto said accommodating hole of said fixing board;
therefore a screw and said clamping section being used to install and disassemble said speaker more easily.

2. The improved speaker fixture assembly of claim 1, wherein said fixing board is designed directly as a loudspeaker box panel.

3. The improved speaker fixture assembly of claim 1, wherein said fixing board is a circular board being aligned and disposed inside a stairway-like groove hole disposed on a loudspeaker box panel.

4. The improved speaker fixture assembly of claim 1, wherein said clamping opening of said clamping section is aslant.
